(19) United States
(12) Patent Application Publication
(10) Pub. No.: US 2026/0041000 A1
(43) Pub. Date: Feb. 5, 2026

(54) SEMICONDUCTOR PACKAGE AND SEMICONDUCTOR MODULE INCLUDING THE SAME

(71) Applicant: Samsung Electronics Co., Ltd., Suwon-si (KR)

(72) Inventors: Kwangho PARK, Suwon-si (KR); Seonghwan JEON, Suwon-si (KR); Minjin KIM, Suwon-si (KR)

(73) Assignee: Samsung Electronics Co., Ltd., Suwon-si (KR)

(21) Appl. No.: 19/026,848

(22) Filed: Jan. 17, 2025

(30) Foreign Application Priority Data
Jul. 31, 2024 (KR) 10-2024-0101390

(51) Int. Cl. H01L 25/16; H01L 23/00; H01L 23/498

(52) U.S. Cl. CPC H01L 25/16; H01L 23/49816; H01L 23/49822; H01L 23/49838; H01L 24/16; H01L 2224/16227; H01L 2924/19041; H01L 2924/19105

(57) ABSTRACT

A semiconductor package includes a package substrate having first and second surfaces opposite to each other, a semiconductor chip and a passive device mounted on the first surface and spaced apart from each other in a first direction parallel to the first surface, and solders on the second surface and spaced apart from each other in the first direction. The package substrate includes first and second via pads adjacent to the first and second surfaces, respectively, and vertically overlapped with each other in a second direction perpendicular to the first surface, and a via structure penetrating the package substrate and connecting the first via pad to the second via pad. The via structure extends in the second direction, between the first and second via pads.

### CROSS-REFERENCE TO RELATED APPLICATIONS

This U.S. non-provisional patent application claims priority under 35 U.S.C. § 119 to Korean Patent Application No. 10-2024-0101390, filed on Jul. 31, 2024, in the Korean Intellectual Property Office, the entire contents of which are hereby incorporated by reference.

### BACKGROUND OF THE INVENTION

The present disclosure relates to semiconductor packages and semiconductor modules including the same.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps.

Recently, the demand for portable electronic devices has been rapidly increasing in the market, and thus, it is desirable to reduce sizes and weights of electronic components constituting the portable electronic devices. In order to achieve this, it is advantageous to develop packaging technologies of reducing a size and a weight of each component and of integrating a plurality of individual components in a single package.

### SUMMARY

Some example embodiments of the inventive concepts provide semiconductor packages with improved electrical and mechanical characteristics and semiconductor modules including the same.

Some example embodiments of the inventive concepts provide semiconductor packages, which may be more easily integrated, and semiconductor modules including the same.

Some example embodiments of the inventive concepts provide semiconductor packages including a substrate, which may be more easily designed, and semiconductor modules including the same.

According to some example embodiments of the inventive concepts, a semiconductor package may include a package substrate having a first surface and a second surface opposite to each other, a semiconductor chip and a passive device mounted on the first surface of the package substrate and spaced apart from each other in a first direction parallel to the first surface, and solders on the second surface of the package substrate and spaced apart from each other in the first direction. The package substrate may include a first via pad adjacent to the first surface, a second via pad adjacent to the second surface and vertically overlapped with the first via pad in a second direction perpendicular to the first surface, and a via structure penetrating the package substrate and connecting the first via pad to the second via pad. The via structure extending in the second direction, between the first via pad and the second via pad. At least a portion of the passive device on the first via pad, and the solders including a first solder on the second via pad.

According to some example embodiments of the inventive concepts, a semiconductor package may include a package substrate having a first surface and a second surface opposite to each other, a semiconductor chip and a capacitor mounted on the first surface of the package substrate and spaced apart from each other in a first direction parallel to the first surface, and solders on the second surface of the package substrate and spaced apart from each other in the first direction. The package substrate may include a via structure penetrating the package substrate in a second direction perpendicular to the first surface. The solders including a first solder electrically connected to the capacitor through the via structure. The first solder vertically overlaps the capacitor in the second direction. The solders include a second solder electrically connected to the semiconductor chip through the package substrate. The second solder may be closer to an edge of the package substrate than the first solder.

According to some example embodiments of the inventive concepts, a semiconductor module may include a module substrate, and a first semiconductor package and a module passive device mounted on a top surface of the module substrate and horizontally spaced apart from each other. The first semiconductor package may include a package substrate having a first surface and a second surface opposite to each other, a semiconductor chip, and a passive device mounted on the first surface of the package substrate and spaced apart from each other in a first direction parallel to the first surface, and solders on the second surface of the package substrate and spaced apart from each other in the first direction. The solders include a first solder and a second solder, the first solder electrically connected to the passive device through the package substrate. The semiconductor chip may be electrically connected to the second solder through the package substrate. The second solder may be closer to an edge of the package substrate than the first solder, and the module substrate may include upper circuit patterns adjacent to the top surface of the module substrate. The second solder may be electrically connected to the module passive device through a corresponding one of the upper circuit patterns.

### BRIEF DESCRIPTION OF THE DRAWINGS

FIG. 1 is a plan view illustrating a semiconductor package according to some example embodiments of the inventive concepts.

FIG. 2 is a sectional view taken along a line A-A′ of FIG. 1.

FIGS. 3 to 5 are sectional views illustrating a method of fabricating a semiconductor package according to some example embodiments of the inventive concepts, taken along the line A-A′ of FIG. 1.

FIG. 6 is a sectional view illustrating a semiconductor module including a semiconductor package according to some example embodiments of the inventive concepts.

### DETAILED DESCRIPTION

Example embodiments of the inventive concepts will now be described more fully with reference to the accompanying drawings, in which example embodiments are shown.

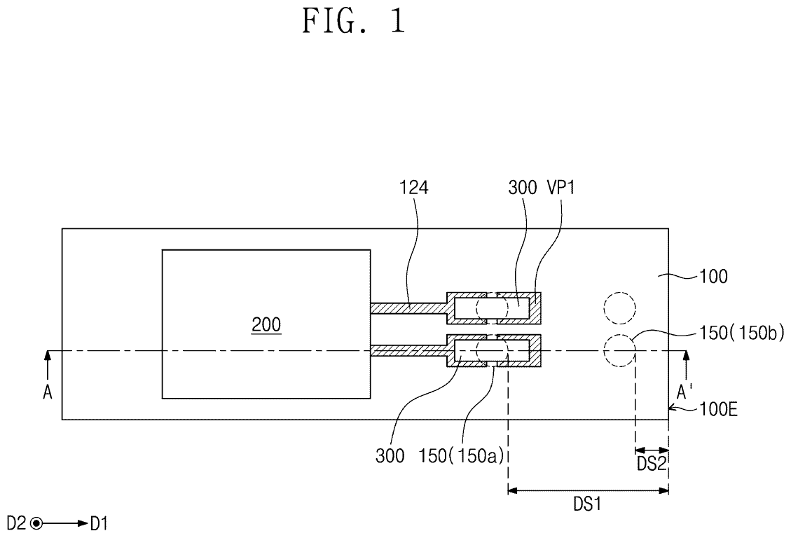

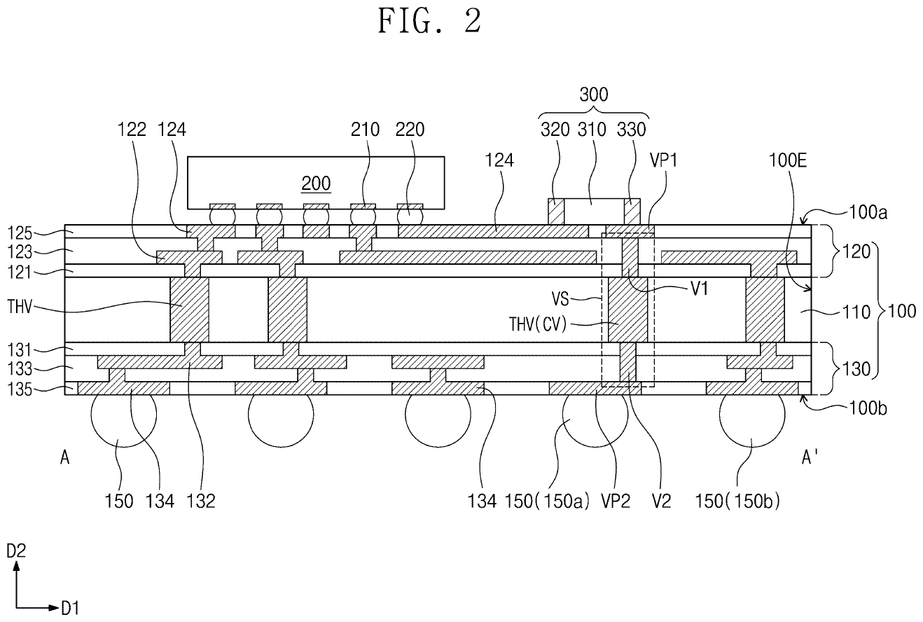

FIG. 1 is a plan view illustrating a semiconductor package according to some example embodiments of the inventive concepts. FIG. 2 is a sectional view taken along a line A-A′ of FIG. 1.

Referring to FIGS. 1 and 2, a semiconductor package may include a package substrate 100 and a semiconductor chip 200 and a passive device 300, which are mounted on the package substrate 100.

The package substrate 100 may have a first surface 100a and a second surface 100b, which are opposite to each other. The semiconductor chip 200 and the passive device 300 may be mounted on the first surface 100a of the package substrate 100 and may be spaced apart from each other in a first direction D1 parallel to the first surface 100a.

The package substrate 100 may include an upper interconnection layer 120 adjacent to the first surface 100a, a lower interconnection layer 130 adjacent to the second surface 100b, a core layer 110 between the upper interconnection layer 120 and the lower interconnection layer 130, and penetration vias THV penetrating the core layer 110. Each of the penetration vias THV may be extended in a second direction D2 perpendicular to the first surface 100a and may be provided to penetrate the core layer 110. In the core layer 110, the penetration vias THV may be spaced apart from each other horizontally (e.g., in the first direction D1) and electrically connect the upper interconnection layer 120 to the lower interconnection layer 130.

In some example embodiments, the core layer 110 may include at least one of insulating materials (e.g., glass, ceramic, and epoxy resin). In some example embodiments, the core layer 110 may include at least one of metallic materials (e.g., stainless steel, aluminum (Al), nickel (Ni), magnesium (Mg), zinc (Zn), tantalum (Ta), or combinations thereof). In the case where the core layer 110 includes a metallic material, an insulating layer may be additionally disposed between each of the penetration vias THV and the core layer 110, and each of the penetration vias THV may be separated from the core layer 110 by the insulating layer. The penetration vias THV may include a metal material (e.g., copper (Cu) or tungsten (W)).

The upper interconnection layer 120 may include upper interconnection patterns 124, which are disposed adjacent to the first surface 100a of the package substrate 100, first intermediate interconnection patterns 122, which are disposed between the core layer 110 and the upper interconnection patterns 124, and upper insulating layers 121, 123, and 125, which are provided to cover the upper interconnection patterns 124 and the first intermediate interconnection patterns 122. The upper insulating layers 121, 123, and 125 may include a first upper insulating layer 121, a second upper insulating layer 123, and a third upper insulating layer 125, which are sequentially stacked on a top surface of the core layer 110.

The first upper insulating layer 121 may be disposed on the top surface of the core layer 110, and the first intermediate interconnection patterns 122 may be disposed on the first upper insulating layer 121. At least some of the first intermediate interconnection patterns 122 may be provided to penetrate the first upper insulating layer 121 and may be electrically connected to the penetration vias THV. The second upper insulating layer 123 may be disposed on the first upper insulating layer 121 to cover the first intermediate interconnection patterns 122. The upper interconnection patterns 124 may be disposed on the second upper insulating layer 123. At least some of the upper interconnection patterns 124 may be provided to penetrate the second upper insulating layer 123 and may be electrically connected to the first intermediate interconnection patterns 122. The third upper insulating layer 125 may be disposed on the second upper insulating layer 123 to cover side surfaces of the upper interconnection patterns 124. Top surfaces of the upper interconnection patterns 124 may not be covered with the third upper insulating layer 125 and may be exposed to the outside.

The upper interconnection patterns 124 and the first intermediate interconnection patterns 122 may include at least one of conductive materials (e.g., copper (Cu), aluminum (Al), silver (Ag), tin (Sn), gold (Au), nickel (Ni), lead (Pb), titanium (Ti), or combinations thereof). In some example embodiments, the first and second upper insulating layers 121 and 123 may include a prepreg, an Ajinomoto build-up film™ (ABF), FR-4, or bismaleimide triazine (BT). The third upper insulating layer 125 may be a solder mask or a solder resist and may include an insulating material.

The upper interconnection layer 120 may further include a first via pad VP1, which is disposed adjacent to the first surface 100a of the package substrate 100, and a first via V1, which is disposed below the first via pad VP1 to penetrate the upper interconnection layer 120.

The first via pad VP1 may be located at the same height as the upper interconnection patterns 124, when measured from the first surface 100a of the package substrate 100. In the present specification, the height may be a length measured in the second direction D2. The first via pad VP1 may be disposed on the second upper insulating layer 123, and the third upper insulating layer 125 may cover a side surface of the first via pad VP1. A top surface of the first via pad VP1 may not be covered with the third upper insulating layer 125 and may be exposed to the outside. The first surface 100a of the package substrate 100 may correspond to a top surface of the third upper insulating layer 125. The top surfaces of the upper interconnection patterns 124 and the first via pad VP1 may not be covered with the third upper insulating layer 125 and may be exposed to the outside. That is, the top surfaces of the upper interconnection patterns 124 and the top surface of the first via pad VP1 may be exposed to the outside of the package substrate 100 near the first surface 100a.

The first via V1 may be extended in the second direction D2 to penetrate the first upper insulating layer 121 and the second upper insulating layer 123. The first via V1 may be connected to the first via pad VP1 and may be connected to a corresponding one of the penetration vias THV. The corresponding penetration via THV connected to the first via V1 may be referred to as a connection via CV. The first via V1 may electrically connect the first via pad VP1 to the connection via CV. The first via pad VP1, the first via V1, and the connection via CV may be vertically overlapped with each other in the second direction D2.

The first via pad VP1 and the first via V1 may include at least one of conductive materials (e.g., copper (Cu), aluminum (Al), silver (Ag), tin (Sn), gold (Au), nickel (Ni), lead (Pb), titanium (Ti), or combinations thereof). The first via pad VP1 and the first via V1 may include the same material as the upper interconnection patterns 124 and the first intermediate interconnection patterns 122.

The lower interconnection layer 130 may include lower interconnection patterns 134, which are disposed adjacent to the second surface 100b of the package substrate 100, second intermediate interconnection patterns 132, which are disposed between the core layer 110 and the lower interconnection patterns 134, and lower insulating layers 131, 133, and 135, which are provided to cover the lower interconnection patterns 134 and the second intermediate interconnection patterns 132. The lower insulating layers 131, 133, and 135 may include a first lower insulating layer 131, a second lower insulating layer 133, and a third lower insulating layer 135, which are sequentially stacked on a bottom surface of the core layer 110.

The first lower insulating layer 131 may be disposed on the bottom surface of the core layer 110, and the second intermediate interconnection patterns 132 may be disposed on the first lower insulating layer 131. At least some of the second intermediate interconnection patterns 132 may be provided to penetrate the first lower insulating layer 131 and may be electrically connected to the penetration vias THV. The second lower insulating layer 133 may be disposed on the first lower insulating layer 131 to cover the second intermediate interconnection patterns 132. The lower interconnection patterns 134 may be disposed on the second lower insulating layer 133. At least some of the lower interconnection patterns 134 may be provided to penetrate the second lower insulating layer 133 and may be electrically connected to the second intermediate interconnection patterns 132. The third lower insulating layer 135 may be disposed on the second lower insulating layer 133 to cover side surfaces of the lower interconnection patterns 134. Bottom surfaces of the lower interconnection patterns 134 may not be covered with the third lower insulating layer 135 and may be exposed to the outside.

The lower interconnection patterns 134 and the second intermediate interconnection patterns 132 may include at least one of conductive materials (e.g., copper (Cu), aluminum (Al), silver (Ag), tin (Sn), gold (Au), nickel (Ni), lead (Pb), titanium (Ti), or combinations thereof). The first and second lower insulating layers 131 and 133 may include a prepreg, an Ajinomoto build-up film™ (ABF), FR-4, or bismaleimide triazine (BT). The third lower insulating layer 135 may be a solder mask or a solder resist and may include an insulating material.

The lower interconnection layer 130 may further include a second via pad VP2, which is disposed adjacent to the second surface 100b of the package substrate 100, and a second via V2, which is disposed on the second via pad VP2 to penetrate the lower interconnection layer 130.

The second via pad VP2 may be located at the same height as the lower interconnection patterns 134, when measured from the second surface 100b of the package substrate 100. The second via pad VP2 may be disposed on the second lower insulating layer 133, and the third lower insulating layer 135 may cover a side surface of the second via pad VP2. A bottom surface of the second via pad VP2 may not be covered with the third lower insulating layer 135 and may be exposed to the outside. The second surface 100b of the package substrate 100 may correspond to a bottom surface of the third lower insulating layer 135. The bottom surfaces of the lower interconnection patterns 134 and the second via pad VP2 may not be covered with the third lower insulating layer 135 and may be exposed to the outside. That is, the bottom surfaces of the lower interconnection patterns 134 and the bottom surface of the second via pad VP2 may be exposed to the outside of the package substrate 100 near the second surface 100b.

The second via V2 may be extended in the second direction D2 to penetrate the first lower insulating layer 131 and the second lower insulating layer 133. The second via V2 may be connected to the second via pad VP2 and may be connected to the connection via CV of the penetration vias THV. The second via V2 may electrically connect the second via pad VP2 to the connection via CV. The second via pad VP2, the second via V2, and the connection via CV may be vertically overlapped with each other in the second direction D2.

The second via pad VP2 and the second via V2 may include at least one of conductive materials (e.g., copper (Cu), aluminum (Al), silver (Ag), tin (Sn), gold (Au), nickel (Ni), lead (Pb), titanium (Ti), or combinations thereof). The second via pad VP2 and the second via V2 may include the same material as the lower interconnection patterns 134 and the second intermediate interconnection patterns 132.

The first via V1, the connection via CV, and the second via V2 may be referred to as a via structure VS. The via structure VS may be disposed between the first and second via pads VP1 and VP2 and may be extended in the second direction D2 to penetrate the package substrate 100. The via structure VS may electrically connect the first via pad VP1 to the second via pad VP2. The first via pad VP1, the via structure VS, and the second via pad VP2 may be vertically overlapped with each other in the second direction D2. In the present specification, the via structure VS is described to include three vias (e.g., the first via V1, the connection via CV, and the second via V2), which are overlapped with each other vertically (e.g., in the second direction D2), but the inventive concepts are not limited to this example. In some example embodiments, the via structure VS may include a plurality of vias, which are overlapped with each other vertically (e.g., in the second direction D2). Alternatively, the via structure VS may be a single via, which is extended in the second direction D2 to penetrate the package substrate 100.

A plurality of solders 150 may be disposed on the second surface 100b of the package substrate 100 and may be spaced apart from each other in the first direction D1. The solders 150 may be disposed on bottom surfaces of the lower interconnection patterns 134 and the second via pad VP2. The solders 150 may be electrically connected to the package substrate 100 through the lower interconnection patterns 134 and the second via pad VP2. In some example embodiments, the solders 150 may include solder balls or solder bumps.

The semiconductor chip 200 may include integrated circuits, and here, the integrated circuits may include, for example, a memory circuit, a logic circuit, or combinations thereof. In some example embodiments, the semiconductor chip 200 may be a system-on-chip (SOC). The semiconductor chip 200 may include chip pads 210, which are adjacent to a bottom surface of the semiconductor chip 200, and connection terminals 220, which are disposed on the chip pads 210. The chip pads 210 may include a conductive material (e.g., a metallic material). The chip pads 210 may be electrically connected to the integrated circuits of the semiconductor chip 200. The connection terminals 220 may be formed of or include a conductive material and may be provided in the form of solder balls, bumps, or pillars. The connection terminals 220 may be electrically connected to the integrated circuits of the semiconductor chip 200 through the chip pads 210.

The semiconductor chip 200 may be electrically connected to the upper interconnection layer 120 of the package substrate 100. The connection terminals 220 of the semiconductor chip 200 may be disposed on top surfaces of corresponding ones of the upper interconnection patterns 124 and may be electrically connected to the corresponding upper interconnection patterns 124. The semiconductor chip 200 may be electrically connected to the package substrate 100 through the chip pads 210, the connection terminals 220, and the corresponding upper interconnection patterns 124.

The passive device 300 may be electrically connected to the upper interconnection layer 120 of the package substrate 100. The passive device 300 may be disposed on the top surface of a corresponding one of the upper interconnection patterns 124 and the top surface of the first via pad VP1 and may be electrically connected to the corresponding upper interconnection pattern 124 and the first via pad VP1. The passive device 300 may be electrically connected to the package substrate 100 through the corresponding upper interconnection pattern 124 and the first via pad VP1.

The semiconductor chip 200 and the passive device 300 may be electrically connected to each other through the upper interconnection layer 120 of the package substrate 100. The corresponding upper interconnection pattern 124 connected to the passive device 300 may be connected to a corresponding one of the connection terminals 220 of the semiconductor chip 200. The passive device 300 may be electrically connected to the semiconductor chip 200 through the corresponding upper interconnection pattern 124 and the corresponding connection terminal 220.

The passive device 300 may be electrically connected to the via structure VS through the first via pad VP1. A first solder 150a of the solders 150 may be disposed on the bottom surface of the second via pad VP2 and may be electrically connected to the second via pad VP2. The first solder 150a may be electrically connected to the via structure VS through the second via pad VP2. The passive device 300 may be electrically connected to the first solder 150a through the first via pad VP1, the via structure VS, and the second via pad VP2. The passive device 300 may be disposed to be vertically overlapped with the first solder 150a in the second direction D2.

The passive device 300 may include a resistor, a capacitor, and/or an inductor. In some example embodiments, the passive device 300 may be a capacitor 300. The capacitor 300 may include a first electrode 320, a second electrode 330, and a dielectric material 310 therebetween. The first electrode 320 of the capacitor 300 may be disposed on the top surface of a corresponding one of the upper interconnection patterns 124 and may be electrically connected to the corresponding upper interconnection pattern 124. The corresponding upper interconnection pattern 124 may be electrically connected to a corresponding one of the connection terminals 220 of the semiconductor chip 200. The first electrode 320 of the capacitor 300 may be electrically connected to the semiconductor chip 200 through the corresponding upper interconnection pattern 124 and the corresponding connection terminal 220. The second electrode 330 of the capacitor 300 may be disposed on the top surface of the first via pad VP1 and may be electrically connected to the first via pad VP1. The second electrode 330 of the capacitor 300 may be electrically connected to the via structure VS through the first via pad VP1. The second electrode 330 of the capacitor 300 may be electrically connected to the first solder 150a through the first via pad VP1, the via structure VS, and the second via pad VP2. The capacitor 300 may be disposed to be vertically overlapped with the first solder 150a in the second direction D2.

The semiconductor chip 200 may be electrically connected to a second solder 150b of the solders 150 through the package substrate 100. At least one of the connection terminals 220 of the semiconductor chip 200 may be electrically connected to a corresponding one of the first intermediate interconnection patterns 122 through a corresponding one of the upper interconnection patterns 124 and may be electrically connected to a corresponding one of the penetration vias THV through the corresponding first intermediate interconnection pattern 122. The second solder 150b may be disposed on a bottom surface of a corresponding one of the lower interconnection patterns 134 and may be electrically connected to the corresponding lower interconnection pattern 134. The second solder 150b may be electrically connected to a corresponding one of the second intermediate interconnection patterns 132 through the corresponding lower interconnection pattern 134 and may be electrically connected to the corresponding penetration via THV through the corresponding second intermediate interconnection pattern 132. The semiconductor chip 200 may be electrically connected to the second solder 150b through the corresponding upper interconnection pattern 124, the corresponding first intermediate interconnection pattern 122, the corresponding penetration via THV, the corresponding second intermediate interconnection pattern 132, and the corresponding lower interconnection pattern 134.

The second solder 150b may be disposed to be closer to an edge 100E of the package substrate 100 than the first solder 150a. The edge 100E of the package substrate 100 may correspond to a side surface of the package substrate 100. The first solder 150a may be spaced apart from the edge 100E of the package substrate 100 by a first distance DS1, and the second solder 150b may be spaced apart from the edge 100E of the package substrate 100 by a second distance DS2. The first and second distances DS1 and DS2 may be distances measured in the first direction D1, and the first distance DS1 may be larger than the second distance DS2.

According to some example embodiments of the inventive concepts, the first via pad VP1 adjacent to the first surface 100a of the package substrate 100 may be vertically overlapped with the second via pad VP2 adjacent to the second surface 100b of the package substrate 100, and the first and second via pads VP1 and VP2 may be electrically connected to each other through the via structure VS penetrating the package substrate 100. The first via pad VP1, the via structure VS, and the second via pad VP2 may be vertically overlapped with each other. The passive device 300 may be disposed on the first via pad VP1, and the first solder 150a may be disposed on the second via pad VP2. The passive device 300 may be electrically connected to the first solder 150a through the first via pad VP1, the via structure VS, and the second via pad VP2, which are vertically overlapped with each other, and additional interconnection patterns may not be required for an electric connection between the passive device 300 and the first solder 150a. That is, the electric connection between the passive device 300 and the first solder 150a may be improved and/or simplified, and thus, the electrical and mechanical characteristics of the semiconductor package may be improved. In addition, since the electric connection between the passive device 300 and the first solder 150a is improved and/or simplified, it may be possible to increase and/or improve a degree of freedom in designing interconnection patterns in the package substrate 100 and thereby more easily increase an integration density of the semiconductor package.

In addition, the second solder 150b, which is electrically connected to the semiconductor chip 200 through the package substrate 100, may be disposed to be closer to the edge 100E of the package substrate 100 than the first solder 150a. Thus, it may be possible to design an interconnection structure more easily in a module substrate mounted with the semiconductor package.

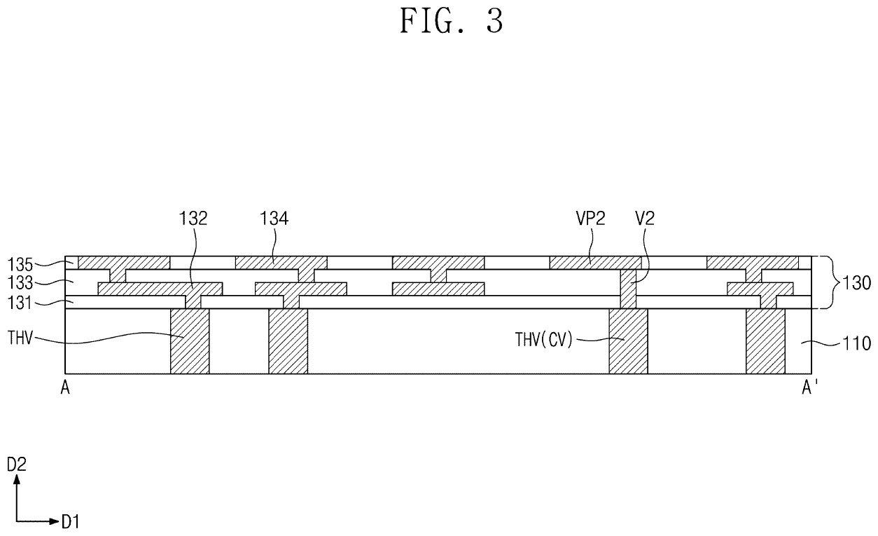

FIGS. 3 to 5 are sectional views illustrating a method of fabricating a semiconductor package according to some example embodiments of the inventive concepts, taken along the line A-A′ of FIG. 1. For concise description, an element described with reference to FIGS. 1 and 2 may be identified by the same reference number without repeating an overlapping description thereof.

Referring to FIG. 3, the core layer 110 may be provided. The penetration vias THV may be formed in the core layer 110. In the core layer 110, the penetration vias THV may be spaced apart from each other horizontally (e.g., in the first direction D1), and each of the penetration vias THV may be extended in the second direction D2 to penetrate the core layer 110. In some example embodiments, the formation of the penetration vias THV may include forming penetration holes to penetrate the core layer 110 and forming a conductive layer to fill the penetration holes.

The lower interconnection layer 130 may be formed on the core layer 110. The formation of the lower interconnection layer 130 may include forming the first lower insulating layer 131 on the core layer 110, forming the second intermediate interconnection patterns 132 on the first lower insulating layer 131, forming the second lower insulating layer 133 on the first lower insulating layer 131 to cover the second intermediate interconnection patterns 132, forming the lower interconnection patterns 134 on the second lower insulating layer 133, and forming the third lower insulating layer 135 on the second lower insulating layer 133 to fill a space between the lower interconnection patterns 134. In some example embodiments, the formation of the second intermediate interconnection patterns 132 may include forming second intermediate contact holes to penetrate the first lower insulating layer 131 and expose the penetration vias THV, forming a second intermediate conductive layer on the first lower insulating layer 131 to fill the second intermediate contact holes, and patterning the second intermediate conductive layer to form the second intermediate interconnection patterns 132. In some example embodiments, the formation of the lower interconnection patterns 134 may include forming lower contact holes to penetrate the second lower insulating layer 133 and expose the second intermediate interconnection patterns 132, forming a lower conductive layer on the second lower insulating layer 133 to fill the lower contact holes, and patterning the lower conductive layer to form the lower interconnection patterns 134.

The formation of the lower interconnection layer 130 may further include forming the second via V2 to penetrate the first and second lower insulating layers 131 and 133, before the formation of the lower interconnection patterns 134 and the third lower insulating layer 135. In some example embodiments, the formation of the second via V2 may include forming a second via hole to penetrate the first and second lower insulating layers 131 and 133 and expose a corresponding one of the penetration vias THV and forming a conductive layer to fill the second via hole. The corresponding penetration via THV may be referred to as the connection via CV. The second via V2 may be formed to be overlapped with the connection via CV vertically (e.g., in the second direction D2).

The formation of the lower interconnection layer 130 may further include forming the second via pad VP2 on the second lower insulating layer 133, before the formation of the third lower insulating layer 135. The second via pad VP2 may be formed on the second via V2 and may be formed to be overlapped with the second via V2 and the connection via CV vertically (e.g., in the second direction D2). In some example embodiments, the second via pad VP2 and the lower interconnection patterns 134 may be formed at the same time. In some example embodiments, the second via pad VP2 may be formed by patterning the lower conductive layer. The third lower insulating layer 135 may be formed to fill a space between the lower interconnection patterns 134 and the second via pad VP2.

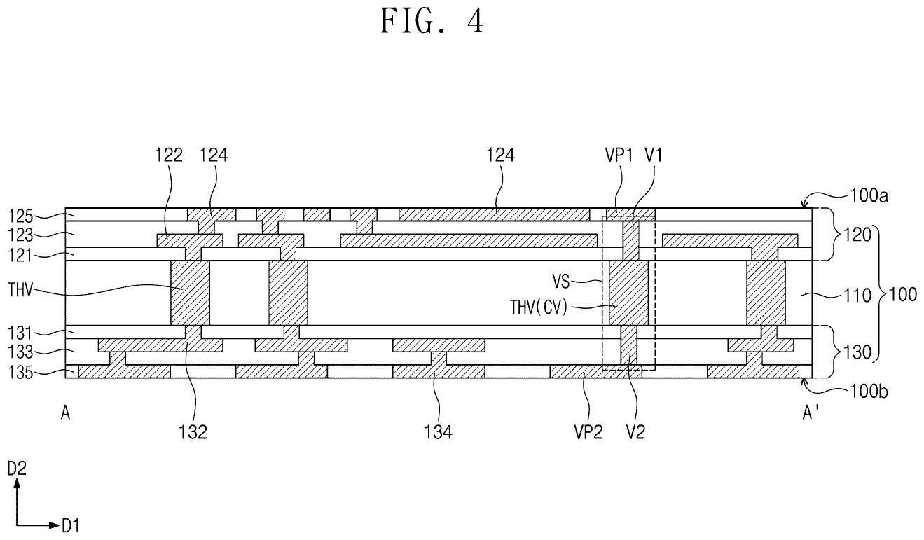

Referring to FIG. 4, the structure of FIG. 3 may be inverted. Thus, the lower interconnection layer 130 may be disposed below the core layer 110. The upper interconnection layer 120 may be formed on the core layer 110, and the core layer 110 may be interposed between the upper interconnection layer 120 and the lower interconnection layer 130.

The formation of the upper interconnection layer 120 may include forming the first upper insulating layer 121 on the core layer 110, forming the first intermediate interconnection patterns 122 on the first upper insulating layer 121, forming the second upper insulating layer 123 on the first upper insulating layer 121 to cover the first intermediate interconnection patterns 122, forming the upper interconnection patterns 124 on the second upper insulating layer 123, and forming the third upper insulating layer 125 on the second upper insulating layer 123 to fill a space between the upper interconnection patterns 124. In some example embodiments, the formation of the first intermediate interconnection patterns 122 may include forming first intermediate contact holes to penetrate the first upper insulating layer 121 and expose the penetration vias THV, forming a first intermediate conductive layer on the first upper insulating layer 121 to fill the first intermediate contact holes, and patterning the first intermediate conductive layer to form the first intermediate interconnection patterns 122. In some example embodiments, the formation of the upper interconnection patterns 124 may include forming upper contact holes to penetrate the second upper insulating layer 123 and expose the first intermediate interconnection patterns 122, forming an upper conductive layer on the second upper insulating layer 123 to fill the upper contact holes, and patterning the upper conductive layer to form the upper interconnection patterns 124.

The formation of the upper interconnection layer 120 may further include forming the first via V1 penetrating the first and second upper insulating layers 121 and 123, before the formation of the upper interconnection patterns 124 and the third upper insulating layer 125. In some example embodiments, the formation of the first via V1 may include forming a first via hole to penetrate the first and second upper insulating layers 121 and 123 and expose the connection via CV, and forming a conductive layer to fill the first via hole. The first via V1 may be formed to be vertically overlapped with the connection via CV vertically (e.g., in the second direction D2).

The formation of the upper interconnection layer 120 may further include forming the first via pad VP1 on the second upper insulating layer 123, before the formation of the third upper insulating layer 125. The first via pad VP1 may be formed on the first via V1 and may be formed to be overlapped with the first via V1 and the connection via CV vertically (e.g., in the second direction D2). The first via pad VP1 and the upper interconnection patterns 124 may be formed at the same time. In some example embodiments, the first via pad VP1 may be formed by patterning the upper conductive layer. The third upper insulating layer 125 may be formed to fill a space between the upper interconnection patterns 124 and the first via pad VP1.

The first via V1, the connection via CV, and the second via V2 may be referred to as the via structure VS. The via structure VS may be disposed between the first and second via pads VP1 and VP2 and may be extended in the second direction D2 to penetrate the package substrate 100. The first via pad VP1, the via structure VS, and the second via pad VP2 may be vertically overlapped with each other in the second direction D2.

The core layer 110, the upper interconnection layer 120, and the lower interconnection layer 130 may constitute the package substrate 100. The package substrate 100 may have the first surface 100a and the second surface 100b, which are opposite to each other. The upper interconnection layer 120 may be adjacent to the first surface 100a, and the lower interconnection layer 130 may be adjacent to the second surface 100b.

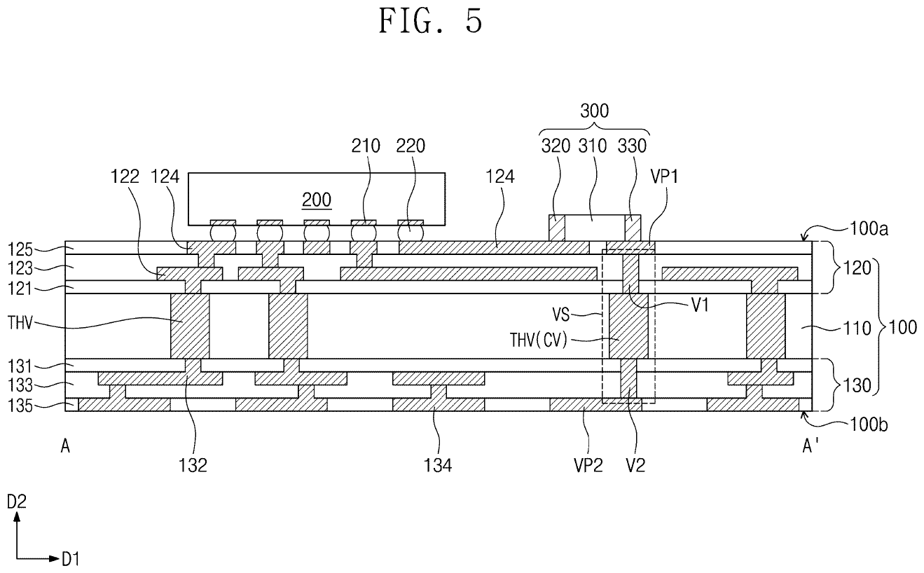

Referring to FIG. 5, the semiconductor chip 200 and the passive device 300 may be mounted on the first surface 100a of the package substrate 100. The semiconductor chip 200 may include the chip pads 210, which are disposed adjacent to the bottom surface of the semiconductor chip 200, and the connection terminals 220, which are disposed on the chip pads 210. The connection terminals 220 of the semiconductor chip 200 may be disposed on top surfaces of corresponding ones of the upper interconnection patterns 124 and may be electrically connected to the corresponding upper interconnection patterns 124.

The passive device 300 may be disposed on the top surface of a corresponding one of the upper interconnection patterns 124 and the top surface of the first via pad VP1 and may be electrically connected to the corresponding upper interconnection pattern 124 and the first via pad VP1. The corresponding upper interconnection pattern 124 connected to the passive device 300 may be connected to a corresponding one of the connection terminals 220 of the semiconductor chip 200. The passive device 300 may be electrically connected to the semiconductor chip 200 through the corresponding upper interconnection pattern 124 and the corresponding connection terminal 220. The passive device 300 may be electrically connected to the via structure VS and the second via pad VP2 through the first via pad VP1.

In some example embodiments, the passive device 300 may be the capacitor 300. The capacitor 300 may include a first electrode 320, a second electrode 330, and a dielectric material 310 therebetween. The first electrode 320 of the capacitor 300 may be disposed on a top surface of the corresponding upper interconnection pattern 124 and may be electrically connected to the semiconductor chip 200 through the corresponding upper interconnection pattern 124 and the corresponding connection terminal 220. The second electrode 330 of the capacitor 300 may be disposed on the top surface of the first via pad VP1 and may be electrically connected to the via structure VS and the second via pad VP2 through the first via pad VP1.

Referring back to FIG. 2, a plurality of solders 150 may be disposed on the second surface 100b of the package substrate 100 and may be spaced apart from each other in the first direction D1. The solders 150 may be disposed on the bottom surfaces of the lower interconnection patterns 134 and the second via pad VP2.

The first solder 150a of the solders 150 may be disposed on the bottom surface of the second via pad VP2 and may be electrically connected to the second via pad VP2. The first solder 150a may be electrically connected to the via structure VS through the second via pad VP2. The passive device 300 may be electrically connected to the first solder 150a through the first via pad VP1, the via structure VS, and the second via pad VP2. The passive device 300 may be disposed to be vertically overlapped with the first solder 150a in the second direction D2.

The second solder 150b of the solders 150 may be disposed on a bottom surface of a corresponding one of the lower interconnection patterns 134 and may be electrically connected to the corresponding lower interconnection pattern 134. The second solder 150b may be electrically connected to the package substrate 100 through the corresponding lower interconnection pattern 134 and may be electrically connected to the semiconductor chip 200 through the package substrate 100. The second solder 150b may be disposed to be closer to the edge 100E of the package substrate 100 than the first solder 150a.

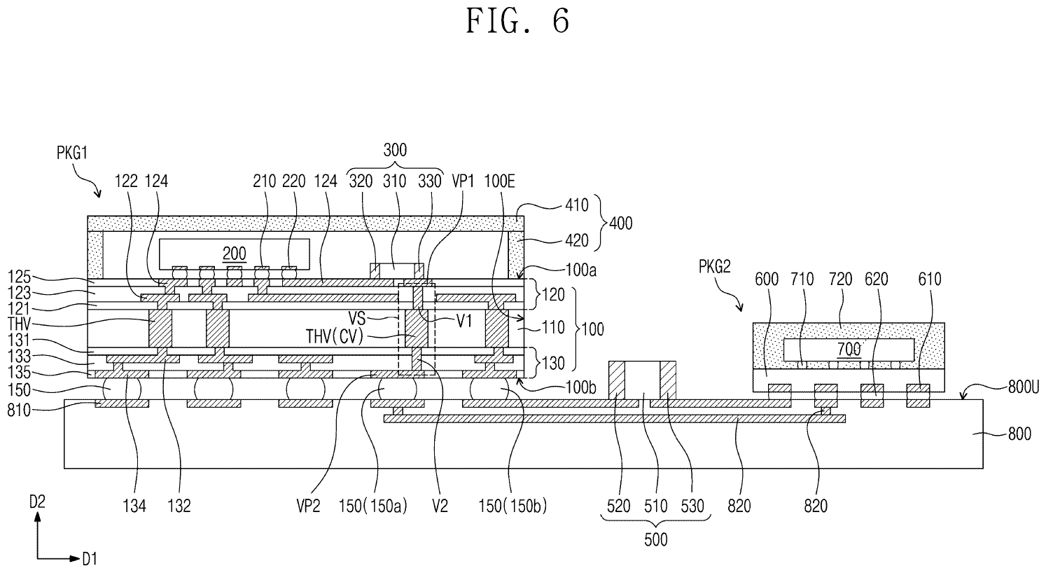

FIG. 6 is a sectional view illustrating a semiconductor module including a semiconductor package according to some example embodiments of the inventive concepts. For concise description, an element described with reference to FIGS. 1 and 2 may be identified by the same reference number without repeating an overlapping description thereof.

Referring to FIG. 6, the semiconductor module may include a module substrate 800 and a plurality of semiconductor packages PKG1 and PKG2 and a module passive device 500, which are mounted on the module substrate 800.

The module substrate 800 may be a printed circuit board. The module substrate 800 may include upper circuit patterns 810, which are adjacent to a top surface 800U of the module substrate 800, and inner circuit patterns 820, which are disposed below the upper circuit patterns 810 and in the module substrate 800. The upper circuit patterns 810 and the inner circuit patterns 820 may include at least one of metallic materials (e.g., copper or aluminum).

The semiconductor packages PKG1 and PKG2 and the module passive device 500 may be mounted on the top surface 800U of the module substrate 800 and may be spaced apart from each other horizontally (e.g., in the first direction D1). The first direction D1 may be parallel to the top surface 800U of the module substrate 800.

The semiconductor packages PKG1 and PKG2 may include a first semiconductor package PKG1 and a second semiconductor package PKG2, which are horizontally spaced apart from each other. The first semiconductor package PKG1 may be configured to have substantially the same features as the semiconductor package described with reference to FIGS. 1 and 2. In some example embodiments, the first semiconductor package PKG1 may further include a housing structure 400, which is disposed on the first surface 100a of the package substrate 100 to cover the semiconductor chip 200 and the passive device 300. In some example embodiments, the housing structure 400 may include a lid 410 and a stiffener 420 supporting the lid 410. In some example embodiments, unlike the illustrated structure, the first semiconductor package PKG1 may include a mold layer (e.g., an epoxy molding compound), which is disposed on the first surface 100a of the package substrate 100 to cover the semiconductor chip 200 and the passive device 300. The first semiconductor package PKG1 may be a semiconductor controller package.

The package substrate 100 of the first semiconductor package PKG1 may be referred to as a first package substrate 100, and the semiconductor chip 200 of the first semiconductor package PKG1 may be referred to as a first semiconductor chip.

The second semiconductor package PKG2 may include a second package substrate 600, a second semiconductor chip 700 mounted on the second package substrate 600, and a mold layer 720, which is disposed on the second package substrate 600 to cover the second semiconductor chip 700. In some example embodiments, the second package substrate 600 may be a printed circuit board (PCB) or a redistribution substrate. The second semiconductor chip 700 may be a memory chip, a logic chip, an application processor (AP) chip, or a system-on-chip (SOC). The mold layer 720 may be disposed on the second package substrate 600 to hermetically seal the second semiconductor chip 700. The mold layer 720 may include, for example, an epoxy molding compound (EMC). In some example embodiments, the second semiconductor chip 700 may be a memory chip, and the second semiconductor package PKG2 may be a semiconductor memory package.

The second semiconductor package PKG2 may further include chip connection bumps 710 disposed between the second semiconductor chip 700 and the second package substrate 600. The chip connection bumps 710 may be formed of or include a conductive material and may include at least one of pillars, bumps, or solder balls. The second semiconductor chip 700 may be electrically connected to the second package substrate 600 through the chip connection bumps 710. The second package substrate 600 may include substrate pads 610, which are disposed adjacent to a bottom surface thereof, and the substrate pads 610 may include a conductive material. The second semiconductor package PKG2 may further include outer connection bumps 620, which are disposed on the substrate pads 610, respectively. The outer connection bumps 620 may be formed of or include a conductive material and may include at least one of pillars, bumps, or solder balls.

The solders 150 of the first semiconductor package PKG1 may be disposed on corresponding ones of the upper circuit patterns 810 of the module substrate 800 and may be electrically connected to the upper circuit patterns 810. The first semiconductor package PKG1 may be electrically connected to the module substrate 800 through the solders 150 and the upper circuit patterns 810. The outer connection bumps 620 of the second semiconductor package PKG2 may be disposed on corresponding ones of the upper circuit patterns 810 of the module substrate 800 and may be electrically connected to the upper circuit patterns 810. The second semiconductor package PKG2 may be electrically connected to the module substrate 800 through the outer connection bumps 620 and the upper circuit patterns 810.

The module passive device 500 may be disposed on corresponding ones of the upper circuit patterns 810 of the module substrate 800 and may be electrically connected to the upper circuit patterns 810. The module passive device 500 may be electrically connected to the module substrate 800 through the upper circuit patterns 810. The module passive device 500 may include a resistor, a capacitor, and/or an inductor.

In some example embodiments, the module passive device 500 may be a module capacitor 500. The module capacitor 500 may include a first module electrode 520, a second module electrode 530, and a module dielectric material 510 therebetween. The first and second module electrodes 520 and 530 of the module capacitor 500 may be disposed on corresponding ones of the upper circuit patterns 810 and may be electrically connected to the upper circuit patterns 810. The module capacitor 500 may be electrically connected to the module substrate 800 through the upper circuit patterns 810.

The first solder 150a of the solders 150 of the first semiconductor package PKG1 may be connected to a corresponding one of the upper circuit patterns 810 and may be electrically connected to a corresponding one of the inner circuit patterns 820 through the corresponding upper circuit pattern 810. The first solder 150a may be electrically connected to the second semiconductor package PKG2 through the corresponding upper circuit pattern 810 and the corresponding inner circuit patterns 820. The passive device 300 of the first semiconductor package PKG1 may be electrically connected to the first solder 150a through the first via pad VP1, the via structure VS, and the second via pad VP2 and may be electrically connected to the second semiconductor package PKG2 through the corresponding upper circuit pattern 810 and the corresponding inner circuit patterns 820 of the module substrate 800.

The second solder 150b of the solders 150 of the first semiconductor package PKG1 may be connected to a corresponding one of the upper circuit patterns 810 and may be electrically connected to the module passive device 500 (e.g., the first module electrode 520) through the corresponding upper circuit pattern 810. The semiconductor chip (e.g., the first semiconductor chip 200) of the first semiconductor package PKG1 may be electrically connected to the second solder 150b through the package substrate 100 and may be electrically connected to the module passive device 500 (e.g., the first module electrode 520) through the corresponding upper circuit pattern 810 of the module substrate 800. The module passive device 500 (e.g., the second module electrode 530) may be electrically connected to the second semiconductor package PKG2 through a corresponding one of the upper circuit patterns 810.

According to some example embodiments of the inventive concepts, the second solder 150b, which is electrically connected to the module passive device 500, may be disposed to be closer to the edge 100E of the package substrate (e.g., the first package substrate 100) than the first solder 150a, and thus, the second solder 150b may be easily connected to the module passive device 500 through the corresponding upper circuit pattern 810. In other words, semiconductor packages according to some example embodiments may provide an improved and/or simpler electric connection between the second solder 150b and the module passive device 500. Accordingly, semiconductor packages according to some example embodiments may provide an improved and/or simpler design interconnection patterns in the module substrate 800, which are used for the electric connection between the first and second semiconductor packages PKG1 and PKG2 and the module passive device 500.

According to some example embodiments of the inventive concepts, a first via pad adjacent to a first surface of a package substrate may be vertically overlapped with a second via pad adjacent to a second surface of the package substrate, and the first via pad and the second via pad may be electrically connected to each other through a via structure penetrating the package substrate. The first via pad, the via structure, and the second via pad may be vertically overlapped with each other. A passive device on the first surface of the package substrate may be electrically connected to a first solder on the second surface of the package substrate through the first via pad, the via structure, and the second via pad, which are vertically overlapped with each other. That is, an electric connection between the passive device and the first solder may be improved and/or simplified, and thus, the electrical and/or mechanical characteristics of the semiconductor package may be improved. In addition, since the electric connection between the passive device and the first solder is simplified and/or improved, it may be possible to increase and/or improve a degree of freedom in designing interconnection patterns in the package substrate and thereby to increase and/or improve an integration density of the semiconductor package more easily.

In addition, according to some example embodiments of the inventive concepts, a second solder, which is electrically connected to the semiconductor chip through the package substrate, may be disposed to be closer to an edge of the package substrate than the first solder. Thus, it may be possible to design an interconnection structure in a module substrate mounted with the semiconductor package more easily.

When the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these shapes should be construed as including a manufacturing or operational tolerance (e.g., ±10%) around the stated shapes.

While example embodiments of the inventive concepts have been particularly shown and described, it will be understood by one of ordinary skill in the art that variations in form and detail may be made therein without departing from the spirit and scope of the attached claims.

1. A semiconductor package, comprising:
a package substrate having a first surface and a second surface opposite to each other;
a semiconductor chip and a passive device on the first surface of the package substrate and spaced apart from each other in a first direction parallel to the first surface; and
solders on the second surface of the package substrate and spaced apart from each other in the first direction,
the package substrate comprising
a first via pad adjacent to the first surface;
a second via pad adjacent to the second surface and vertically overlapped with the first via pad in a second direction perpendicular to the first surface; and
a via structure penetrating the package substrate and connecting the first via pad to the second via pad,
the via structure extending in the second direction between the first via pad and the second via pad,
at least a portion of the passive device on the first via pad, and
the solders including a first solder on the second via pad.

2. The semiconductor package of claim 1, wherein
the package substrate comprises upper interconnection patterns adjacent to the first surface, and
the semiconductor chip is electrically connected to the package substrate and the passive device through corresponding ones of the upper interconnection patterns.

3. The semiconductor package of claim 2, wherein the first via pad is located at a same height as the upper interconnection patterns, measured from the first surface of the package substrate.

4. The semiconductor package of claim 3, wherein a top surface of the first via pad and top surfaces of the upper interconnection patterns are exposed to an outside of the package substrate near the first surface.

5. The semiconductor package of claim 3, wherein
the package substrate comprises first intermediate interconnection patterns below the upper interconnection patterns and in the package substrate,
the solders include a second solder, the second solder electrically connected to the semiconductor chip through a corresponding one of the first intermediate interconnection patterns, and
the second solder is closer to an edge of the package substrate than the first solder.

6. The semiconductor package of claim 3, wherein
the package substrate comprises lower interconnection patterns adjacent to the second surface,
the solders are electrically connected to the package substrate through the lower interconnection patterns, and
the second via pad is at a same height as the lower interconnection patterns, measured from the second surface of the package substrate.

7. The semiconductor package of claim 6, wherein a bottom surface of the second via pad and bottom surfaces of the lower interconnection patterns are exposed to an outside of the package substrate near the second surface.

8. The semiconductor package of claim 6, wherein
the solders include a second solder, the second solder electrically connected to the package substrate through a corresponding one of the lower interconnection patterns, and
the second solder is closer to an edge of the package substrate than the first solder.

9. The semiconductor package of claim 1, wherein the passive device vertically overlaps with the first solder in the second direction.

10. The semiconductor package of claim 1, wherein the passive device is a capacitor.

11. The semiconductor package of claim 10, wherein
the package substrate comprises upper interconnection patterns adjacent to the first surface,
the first via pad is located at a same height as the first upper interconnection patterns, measured from the first surface of the package substrate,
the capacitor comprises a first electrode, a second electrode, and a dielectric material therebetween,
the first electrode of the capacitor is electrically connected to the semiconductor chip through a corresponding one of the upper interconnection patterns, and
the second electrode of the capacitor is connected to the first via pad.

12. The semiconductor package of claim 11, wherein the capacitor and the first solder vertically overlap with each other in the second direction.

13. The semiconductor package of claim 12, wherein
the package substrate comprises lower interconnection patterns adjacent to the second surface,
the second via pad is at a same height as the lower interconnection patterns, measured from the second surface of the package substrate,
the solders include a second solder, the second solder electrically connected to the package substrate through a corresponding one of the lower interconnection patterns, and
the second solder is closer to an edge of the package substrate than the first solder.

14. The semiconductor package of claim 1, wherein
the package substrate comprises,
an upper interconnection layer adjacent to the first surface, the upper interconnection layer comprising the first via pad;
a lower interconnection layer adjacent to the second surface, the lower interconnection layer comprising the second via pad; and
a core layer between the upper interconnection layer and the lower interconnection layer,
the via structure comprises,
a first via penetrating the upper interconnection layer and connected to the first via pad;
a second via penetrating the lower interconnection layer and connected to the second via pad; and
a connection via penetrating the core layer and connected to the first via and the second via.

15. The semiconductor package of claim 14, wherein the first via, the second via, and the connection via are vertically overlapped with each other in the second direction.

16. A semiconductor package, comprising:
a package substrate having a first surface and a second surface, opposite to each other;
a semiconductor chip and a capacitor mounted on the first surface of the package substrate and spaced apart from each other in a first direction parallel to the first surface; and
solders on the second surface of the package substrate and spaced apart from each other in the first direction,
the package substrate comprises a via structure penetrating the package substrate in a second direction perpendicular to the first surface,
the solders include a first solder electrically connected to the capacitor through the via structure,
the first solder vertically overlaps the capacitor in the second direction,
the solders include a second solder electrically connected to the semiconductor chip through the package substrate, and
the second solder closer to an edge of the package substrate than the first solder.

17. The semiconductor package of claim 16, wherein
the package substrate comprises upper interconnection patterns adjacent to the first surface and a first via pad adjacent to the first surface,
the first via pad is at a same height as the upper interconnection patterns, measured from the first surface of the package substrate,
the capacitor comprises a first electrode, a second electrode, and a dielectric material therebetween,
the first electrode of the capacitor is electrically connected to the semiconductor chip through a corresponding one of the upper interconnection patterns, and
the second electrode of the capacitor is on the first via pad and is electrically connected to the via structure through the first via pad.

18. The semiconductor package of claim 17, wherein
the package substrate comprises lower interconnection patterns adjacent to the second surface and a second via pad adjacent to the second surface,
the second via pad is at a same height as the lower interconnection patterns, measured from the second surface of the package substrate,
the first solder is on the second via pad and is electrically connected to the via structure through the second via pad, and
the second solder is electrically connected to the package substrate through a corresponding one of the lower interconnection patterns.

19. The semiconductor package of claim 18. wherein the first via pad, the via structure, and the second via pad are vertically overlapped with each other in the second direction.

20. A semiconductor module, comprising:
a module substrate; and
a first semiconductor package and a module passive device mounted on a top surface of the module substrate and horizontally spaced apart from each other,
the first semiconductor package comprising
a package substrate having a first surface and a second surface opposite to each other;
a semiconductor chip and a passive device mounted on the first surface of the package substrate and spaced apart from each other in a first direction parallel to the first surface; and
solders on the second surface of the package substrate and spaced apart from each other in the first direction,
the solders including a first solder and a second solder,
the first solder electrically connected to the passive device through the package substrate,
the semiconductor chip electrically connected to the second solder through the package substrate,
the second solder closer to an edge of the package substrate than the first solder,
the module substrate comprising upper circuit patterns adjacent to the top surface of the module substrate, and
the second solder electrically connected to the module passive device through a corresponding one of the upper circuit patterns.

21.-22. (canceled)
